(19) United States
(12) Patent Application Publication
(10) Pub. No.: US 2010/0293442 A1
(43) Pub. Date: Nov. 18, 2010

(54) MULTI-TAP FREQUENCY DOMAIN EQUALIZATION WITH DECISION FEEDBACK AND TRELLIS DECODING

(75) Inventors: Guillermo Del Angel, Belmont, MA (US); Arnon Friedmann, Marlboro, MA (US); Stuart Sandberg, Acton, MA (US); Richard Gross, Acton, MA (US); Peter Heller, Sommerville, MA (US)

Correspondence Address: Jason H. Vick;Sheridan Ross, PC, Suite # 1200, 1560 Broadway, Denver, CO, 80202, US

(73) Assignee: AWARE, IN., Bedford, MA (US)

(21) Appl. No.: 12/783,733

(22) Filed: May 20, 2010

Related U.S. Application Data
(63) Continuation of application No. 11/748,806, filed on May 15, 2007.
Application No. 11/748,806 is a division of application No. 10/631,745, filed on Aug. 1, 2003, now abandoned.
(60) Provisional application No. 60/400,550, filed on Aug. 1, 2002.

(51) Int. Cl. H03M 13/03; G06F 11/00

(52) U.S. Cl. 714/792; 714/E11.001

(57) ABSTRACT

An input estimator is based on a combined MFDQ-DF and trellis for use in, for example, an ADSL environment. In particular, for an ADSL implementation, the system will have one feedback tap for the decision feedback. However, it should be appreciated that the idea and basic concept of using the structure of a trellis to aid in determining the feedback point can be extended to any system using a feedback equalizer to estimate input to a trellis decoder.

### RELATED APPLICATION DATA

This application claims the benefit of and priority under 35 U.S.C. §119(e) to U.S. Patent Application Ser. No. 60/400,550, filed Aug. 1, 2002, entitled “Combined Multi-Tap Frequency Domain Equalization With Decision Feedback And Trellis Decoding,” and is related to U.S. patent application Ser. No. 10/211,425 filed Aug. 2, 2002 entitled “Systems and Methods For Multicarrier Modulation Using Multi-Tap Frequency-Domain Equalizer and Decision Feedback,” both of which are incorporated herein by reference in their entirety.

### BACKGROUND OF THE INVENTION

1. Field of the Invention

The system and methods of this invention generally relate to communication systems. In particular, the systems and methods of this invention relate to combined frequency domain equalization with decision feedback and trellis decoding.

2. Description of Related Art

In multicarrier modulation, a transmission channel is partitioned into a multitude of sub-channels, each with its own associated carrier. In implementations of multicarrier modulation known as discrete multitone (DMT) transmission, or orthogonal frequency division multiplexing (OFDM), the generation and modulation of the sub-channels is accomplished digitally, using an orthogonal transformation on each of a sequence of blocks, i.e., frames, of the data stream. A receiver performs the inverse transformation on segments of the sampled waveform to demodulate the data. In the implementation of DMT used as the signaling standard for asymmetric digital subscriber lines (ADSL), the transforms used for demodulation and modulation are the Discrete Fourier Transform (DFT) and its inverse, respectively. Further information regarding the asymmetric digital subscriber line standard can be found in the article Asymmetric Digital Subscriber Line (ADSL) Metallic Interface, ANSI T1E1.4/94-007R8, 1994, incorporated herein by reference in its entirety.

In another implementation, referred to as discrete wavelet multitone (DWMT) transmission, a discrete wavelet transform and its inverse are employed as discussed in M. A. Tzannes et al, “The DWMT: A Multicarrier Transceiver for ADSL Using M-Band Wavelets,” ANSI Standard Committee T1E1.4 contribution 93-067, March 1993, M. A. Tzannes, “System Design Issues for the DWMT Transceiver,” ANSI Standard Committee T1E1.4 contribution 93-100, April 1993 and M. A. Tzannes et al, “DMT Systems, DWMT Systems and Digital Filter Banks,” Proc. ICC 1994, all of which are incorporated herein by reference in their entirety.

Thus, in a multicarrier system, a communication path having a fixed bandwidth is divided into a number of sub-bands having different frequencies. The width of the sub-bands is chosen to be small enough to allow the distortion in each sub-band to be modeled by a single attenuation and phase shift for the band. If the noise level in each band is known, the volume of data sent in each band may be optimized by choosing a symbol set having the maximum number of symbols consistent with the available signal to noise ratio of the channel. By using each sub-band at its maximum capacity, the amount of data that can be transmitted in the communication path is maximized.

In practice, such systems are implemented by banks of digital filters which make use of Fast Fourier Transforms (FFT). In the case in which a single data stream is to be transmitted over the communication path is broken into M sub-bands, during each communication cycle, the portion of the data stream to be transmitted is converted to M QAM symbols chosen to match the capacity of the various channels.

The time domain signal to be sent on the communication path is obtained by selecting a QAM point on each sub-carrier and then adding the modulation carriers to form the signal to be placed in the communication path. This operation is normally carried out by transforming the vector of M symbols via the inverse Fourier transform to generate N, where N represents the size of the transform, time domain values that are sent in sequence on the communication path. At the other end of the communications path, the N time domain values are accumulated and transformed via a Fourier transform to recover the original M symbols after equalization of the transformed data to correct for the attenuation and phase shifts that may have occurred in the channels.

One type of problem encountered in transmission systems is intersymbol interference (ISI). When the time domain values are transmitted, the values are spread over time by the impulse response of the system. Often, a guard band is included to prevent previous frames from interfering with subsequent frames, but these guard bands are often too small to be sufficient on their own. Also, values from within the same frame can interfere with each other to cause ISI, sometimes referred to as intersubchannel interference. The time domain equalizer works to shorten the overall length of the impulse response but usually does not remove all of the ISI.

Therefore, the symbol decoded by the subscriber will include interference from other symbols in other sub-bands and/or earlier or later symbols transmitted in the subscriber's sub-band. This type of interference is further aggravated by the high side lobes in the sub-bands provided by the Fourier transform. Further information regarding multicarrier transmission systems can be obtained from U.S. Pat. No. 5,636,246 entitled “Multicarrier Transmission System,” incorporated herein by reference in its entirety.

As a particular example, in current ADSL systems, an FFT is used to demodulate the incoming signal. Each complex output from the FFT is passed through a one tap (complex), frequency domain equalizer (FDQ). The output of the FDQ is an estimate of the transmitted QAM symbol. If the ADSL system uses trellis-coded modulation, the output of the FDQ is then used as input to a separate trellis decoder.

An exemplary method to improve the single tap FDQ combines multiple FFT outputs as well as decision feedback taps to create an estimate of the transmitted QAM symbol. This method is known as multi-tap frequency-domain equalization and decision feedback (MFDQ-DF) and can be expressed by a complex output. In particular, if the complex output of the FFT for tone i is given by fᵢ, then the complex output of the MFDQ-DF algorithm Rᵢ is given by:

$${R}_{i} {\sum }_{j = 0}^{N - 1} {A}_{i , j} {f}_{i - j} + {\sum }_{j = 1}^{M} {B}_{i , j} {\hat{D}}_{i - j} \qquad ( 1 )$$

where \hat{D}ᵢ is the constellation point closest to the received point Rᵢ, A_{i,j} is the complex feed-forward coefficient from tone j to tone i, and B_{i,j} is the complex feedback coefficient from tone j to tone i.

### SUMMARY OF THE INVENTION

Since each Rᵢ is dependent on decisions made on earlier tones, this algorithm is subject to burst errors when incorrect decisions are made for \hat{D}ᵢ. However, this may create discrepancies when the output of the MFDQ algorithm is used as input to a separate trellis decoder. Although the input to the trellis decoder is the soft information Rᵢ values, if there are multiple consecutive feedback errors used in the creation of these values, then the trellis may be unable to decode correctly.

An exemplary method of improving upon this approach is to use more than just one feedback value to create more than one received point for each tone. The basic concept utilizes the structure of the trellis to aid in determining a feedback point. While possible to design a new trellis that incorporates both the states of the convolution code and the different feedback values, en exemplary aspect of this invention is directed toward maintaining the trellis structure and altering only the branch metric computation. However, and in general, these basic concepts can be applied to any detection system employing MFDQ-DF and a trellis decoder.

As discussed in the related application, the four closest points to any received point are all in different cosets. Therefore, instead of choosing \hat{D}ᵢ and using this term for the feedback expression, \hat{D}ᵢ^{k} can be selectively used where \hat{D}ᵢ^{k} denotes the closest constellation point in coset k to Rᵢ. The choice of which coset to use can be determined from the branch label of the trellis.

For an ideal transmission channel, the receiver transform output is a replica of the modulating data, due to the orthogonality (Nyquist) properties of the particular transform used. However, without compensation, and as discussed above, the practical channels can contain severe intersubchannel and interframe interference. That is, the receiver transform output for sub-channel m₁ and frame i₁ has a contribution not only from sᵢ_{₁}^{m}^{₁} but also from sᵢ^{m} for {m, i}≠{m₁,i₁}, where sᵢ^{m} denotes the symbol transmitted in sub-channel in for frame i. For sake of clarity, in the following disclosure a distinction between intersubchannel and interframe interference will not be made, but rather the combination of the two referred to as intersymbol interference (ISI). However, it is to be appreciated, that the receiver transform outputs can also have contributions from independent background noise, which, also for sake of clarity, will be disregarded for this discussion.

Multicarrier systems typically employ equalization to compensate for the effects of ISI. Such equalization is typically done in time-domain and the frequency-domain. For time-domain equalization (TDQ), and adaptive filter is trained, then applied to the sequence of samples at the receiver, before the sequence is passed to the receiver transform. For frequency-domain equalization (FDQ), processing is employed on the receiver transform outputs.

Let sᵢ_{₁}^{m}^{₁} denote the actual transmitted symbol, and let Sᵢ_{₁}^{\hat{m}}^{₁} denote the FDQ output for subchannel m₁ and frame i₁. The desired net effect of TDQ and FDQ is for Sᵢ_{₁}^{\hat{m}}^{₁} equal to Sᵢ_{₁}^{m}^{₁}, plus only a very small contribution form ISI. The receive can make a decision on the value for sᵢ_{₁}^{m}^{₁} by quantizing Sᵢ_{₁}^{\hat{m}}^{₁} to the nearest constellation point. This decision will be denoted by dᵢ_{₁}^{m}^{₁}.

Typically, the time-domain equalizer is relied on to perform the bulk of the ISI mitigation, with the frequency domain equalization being used only to perform a phase and amplitude correction for the channel/TDQ combination at the given sub-channel center frequency. In these schemes, each TDQ is implemented as a single-tap complex multiply, applied to the associated sub-channel output.

However, as discussed in U.S. Pat. No. 5,636,246, additional ISI suppression can be obtained by allowing each FDQ to have multiple taps, and combining the receiver transform outputs for several neighboring sub-channel, frame pairs. However, as discussed in the related application, further reduction in ISI can be achieved by incorporating feedback from neighboring sub-channel, frame pairs in the frequency-domain equalizer combiner.

The systems and methods discussed herein will focus on the application of a combined MFDQ-DF and trellis in an ADSL environment. In particular, the ADSL will have one feedback tap for the decision feedback. However, it should be fully appreciated, that this idea and basic concept discussed herein can be extended to any system using a feedback equalizer to estimate input to a trellis decoder.

Accordingly, aspects of the invention relate to reducing intersymbol interference.

Additional aspects of the invention relate to reducing intersymbol interference through the use of feedback.

Additional aspects of the invention relate to reducing intersymbol interference through the use of combined feedback and trellis decoding.

Aspects of the invention further relate to combining multiple FFT outputs as well as decision feedback and trellis decoding to create an estimate of a transmitted QAM symbol.

Aspects of the invention additionally relate to using a multi-tap frequency domain equalizer with decision feedback and trellis decoding to, for example, minimize intersymbol interference in a multicarrier modulation communication system.

Aspects of the invention further relate to using feedback with a trellis structure on a system using a feedback equalizer to estimate input to a trellis decoder.

Aspects of the invention further relate to using feedback with a trellis structure on a system using a feedback equalizer to estimate input to an integrated trellis decoder.

These and other features and advantages of this invention are described in, or are apparent from, the following detailed description of the embodiments.

### BRIEF DESCRIPTION OF THE DRAWINGS

The embodiments of the invention will be described in detail, with reference to the following figures, wherein:

FIG. 1 is a functional block diagram illustrating an equalizer portion of a receiver;

FIG. 2 is a functional block diagram illustrating a portion of a receiver according to an exemplary embodiment of this invention;

FIG. 3 is an exemplary branch metric computation according to this invention;

FIG. 4 is an exemplary partial branch metric computation according to this invention;

FIG. 5 is a flowchart illustrating an exemplary branch metric determination procedure according to this invention; and

FIG. 6 is a graph illustrating an exemplary performance comparison between a stand-alone MFDQ system, a combined trellis and MFDQ system according to the principles of this invention and an ideal case.

### DETAILED DESCRIPTION OF THE INVENTION

The exemplary systems and methods of this invention will be described in relation to communications systems and components, and more particularly to multicarrier modulation communications. However, to avoid unnecessarily obscuring the present invention, the following description omits well-known structures and devices that may be shown in block diagram form or otherwise summarized. For the purposes of explanation, numerous specific details are set forth in order to provide a thorough understanding of the present invention. It should be appreciated however that the present invention may be practiced in a variety of ways beyond these specific details. For example, the systems and methods of this invention can generally be applied to any type of communication system including wireless communication systems, such as wireless LANs, power line communications, or any other system or combination of systems that use multicarrier communication or any other form of modulation in which it is desired to, for example, reduce intersymbol interference.

Furthermore, while the exemplary embodiments illustrated herein show the various components of the communication system collocated, it is to be appreciated that the various components of the system can be located at distant portions of a distributed network, such as a telecommunications network and/or the Internet, or within a dedicated receiver having the components capable of performing the functionality associated with this invention incorporated therein. Thus, it should be appreciated that the components of the system can be combined into one or more devices or collocated on a particular node of a distributed network, such as a telecommunications network. As will be appreciated from the following description, and for reasons of computational efficiency, the components of the system can be arranged at any location within a distributed network without affecting the operation of the system.

Furthermore, it should be appreciated that the various links connecting the elements can be wired or wireless links, or a combination thereof, or any other known or later developed element(s) that is capable of supplying and/or communicating data to and from the connected elements. Additionally, the term module as used herein can refer to any known or later developed hardware, software, or combination of hardware and software that is capable of performing the functionality associated with that element.

Likewise, while it would be possible to design a new trellis that incorporates both the states of the convolution code and the different feedback values, an exemplary embodiment of this invention is directed toward maintaining the trellis structure and altering only the branch metric computation. Nevertheless, and in general, these basic concepts can be applied to any system employing MFDQ-DF and a trellis decoder.

In accordance with an exemplary embodiment of this invention, and in relation to a specific application where the systems and methods disclosed herein will be applied to an ADSL system, the following discussion is directed thereto. In particular, in ADSL, a 16 state 4D Wei code is used. See, for example, G.992.1 ITU Recommendation: Asymmetrical Digital Subscriber Line (ADSL) Transceivers and “Trellis-Coded Modulation with Multidimensional Constellations,” Wei, IEEE Trans. on Information Theory, Vol. IT33, No. 4, July 1987, both of which are incorporate herein by reference in there entirety.

In accordance with this exemplary embodiment, the trellis encodes two tones at a time and each step in the trellis requires two received tones in order to determine a branch metric. The QAM constellations are partitioned into 4 groups called cosets. Since the QAM symbols are chosen from a two dimensional grid, these cosets are called the 2D cosets. A pair of two, 2D cosets are considered a 4D coset. The possible 4D cosets are further grouped into 8 sets, where each of these 8 sets contains two pairs of 2D cosets. Each branch in the trellis is labeled with one of these eight 4D cosets. Since each 4D coset can be one of two pairs of 2D cosets, each branch can be thought of as two parallel branches where each parallel branch has a single pair of 2D cosets as its label.

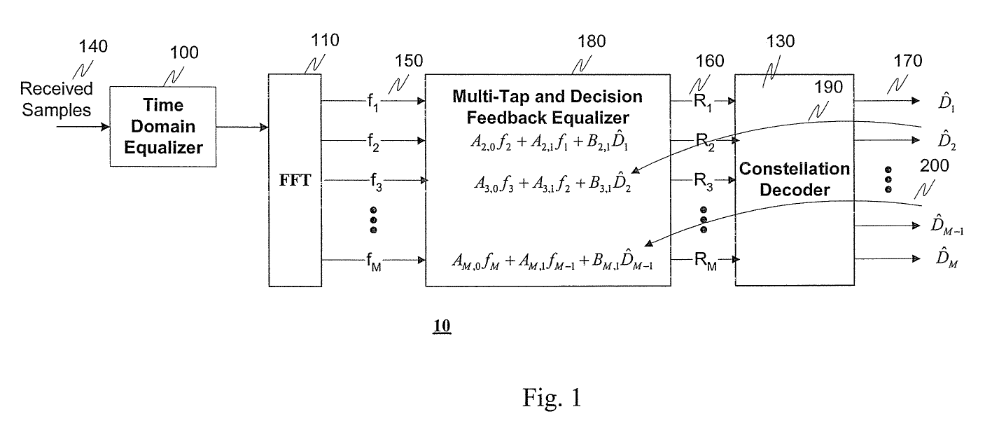

FIG. 1 illustrates a portion of receiver 10. In particular, the receiver 10 comprises a time domain equalizer 100, a fast Fourier transform module 110, a frequency domain equalizer 120 and a constellation decoder 130. As previously discussed, during typical operation a plurality of received samples 140 are received at the time-domain equalizer 100. The time-domain equalizer 100 applies adaptive filtering to the sequence of samples and passes the sequence to the fast Fourier transform module 110. The fast Fourier transform module 110 outputs a complex output f_{M} for each tone M in the set of total tones M in each frame. The multi-tap and decision feedback equalizer 180 then performs a single-tap complex multiply to each associated sub-channel resulting in the received point R_{M} 160. The constellation decoder 130 then determines the constellation point \hat{D}ᵢ closest to the received point R_{M} for each tone.

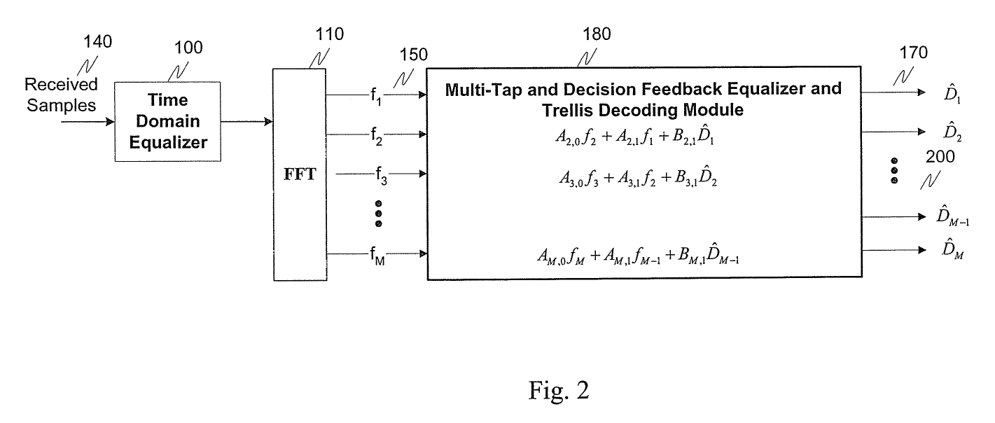

Specifically, FIG. 1 illustrates graphically how feedback is used in the multi-tap and decision feedback equalizer 180. In particular, FIG. 2 comprises one or more received samples 140, a time-domain equalizer 100, an FFT module 110, a plurality of complex outputs 150, a multi-tap decision feedback equalizer 180, a plurality of determined received points 160 corresponding to a respective tone, a constellation decoder 130 and plurality of output constellation points 170 that were determined to be closest to the received point 160. The operation of the equalizer 180 in FIG. 1 is comparable to that in a typical operation, with the exception of constellation points 170 being fed back to aid in determining the R_{M} for another tone. In this simple particular example, \hat{D}₂ 190 is fed back to tone 3 and \hat{D}_{M-1} 200 is fed back to tone M. It is to be appreciated that, in general, the constellation points 170 can be fed back to any one or more other tones to aid in determining the received point R_{M}. For example, the system can begin with the determination of \hat{D}_{M} and proceed “backwards” until \hat{D}₁ is determined. Alternatively, the system can jump around between tones with the only limitation being R_{M} is dependent on decisions made on earlier tones.

Additionally, it is to be appreciated that any constellation point 170 can be used as feedback alone or in combination, with other constellation points and, as discussed above, can be either forward looking or backward looking, or a combination thereof, for feedback terms.

FIG. 2 is a block diagram representing a portion of a communications device, such as a receiver, that employs feedback equalization and trellis decoding. In particular, the system comprises a time domain equalizer 100, a fast forward transform module 110 and a multi-tap and decision feedback equalizer and trellis decoding module 180. As previously discussed, a plurality of received samples 140 are received at the time-domain equalizer 100. The time-domain equalizer 100 applies adaptive filtering to the sequence of samples and passes of sequence to the FFT module 110. The FFT module 110 outputs a complex output F_{M} for each tone M.

The multi-tap and decision feedback equalizer and trellis decoding module 180 determines branch metrics from pairs of received tones, where the received tones, or points, are estimated QAM symbols from the output of either a traditional FDQ, or in this particularly exemplary embodiment, the output of the multi-tap decision feedback equalizer. The branch metric value is a sum of the squared Euclidean distance from each of the 2 received points to the closest constellation point in the coset as defined by the trellis branch label. Since there are two parallel branches into each state, two distance values are determined and the minimum for the branch metric chosen. The branch metric computation can then be rewritten as:

BM_{m′,m}ⁿ=min{ [symbol] \hat{D}εC_{m′m}^{1,1},R₂ₙ₋₁ [symbol] + [symbol] \hat{D}εC_{m′,m}^{1,2},R₂ₙ [symbol] , [symbol] \hat{D}εC_{m′,m}^{2,1},R₂ₙ₋₁ [symbol] + [symbol] \hat{D}εC_{m′,m}^{2,2},R₂ₙ [symbol] } (2)

where Eq. 2 is the branch metric from state m′ to state m for step n of the trellis. The notation \hat{D}εC_{m′,m}^{i,j} denotes the closest constellation point in the j^{th} coset on the i^{th} parallel branch from state m′ to state m. The notation [symbol] X,Y [symbol] represents the squared Euclidean distance between points X and Y. Note there are 2 parallel branches and 2 cosets per branch so the values of i and j only take on the values {1,2}. Also note that the first term in the min expression is the sum of the distances for the 2 cosets on the first parallel branch, while the second term is the sum of the distance on the second parallel branch.

Looking at a specific example, consider the case where there are 2 feedforward taps and 1 feedback tap in the MFDQ-DF equalizer portion of the multi-tap and decision feedback equalizer and trellis decoding module 180. Eq. 2 can thus be simplified to:

Rᵢ=A_{i,0}fᵢ+A_{i,1}fᵢ₋₁+B_{i,1}\hat{D}ᵢ₋₁ (3).

When combining the MFDQ and the trellis, only the feedback portion need change for the expression \hat{D}ᵢ₋₁ the feedfoward inputs are still the FFT outputs for all states of the trellis. Thus, the key in regulating the performance is in determining the proper value of to use in the determination of the branch metrics.

Furthermore, in order to combine the multi-tap decision feedback equalizer and trellis decoding module 180, is necessary to change the branch metric expression in such a way that different feedback terms are used in the determinations for different portions of the branch metric. For example, if a branch metric calls for the sum of the distance to coset 1 and coset 3, then the feedback decision used to determine the received point for the 2^{nd} term should come from coset 1. If the MFDQ and trellis operations are performed independently, then there is no guarantee that this will be the case. This implies that it may be necessary to determine many received values for each tone, each of these values depending on the choice of feedback for the branch of interest. Accordingly, it may not be possible to apriori determine the received tone and then proceed to the branch metric determination.

For each step of the trellis, and for each state in the trellis, the most likely path to that state is maintained. This path will be referred to as the “survivor path.” Each survivor path corresponds to a decision, i.e., estimated transmitted QAM symbols, on a pair of received tones entering a given state, and can be used as feedback for the first tone on the branch metrics exiting that state.

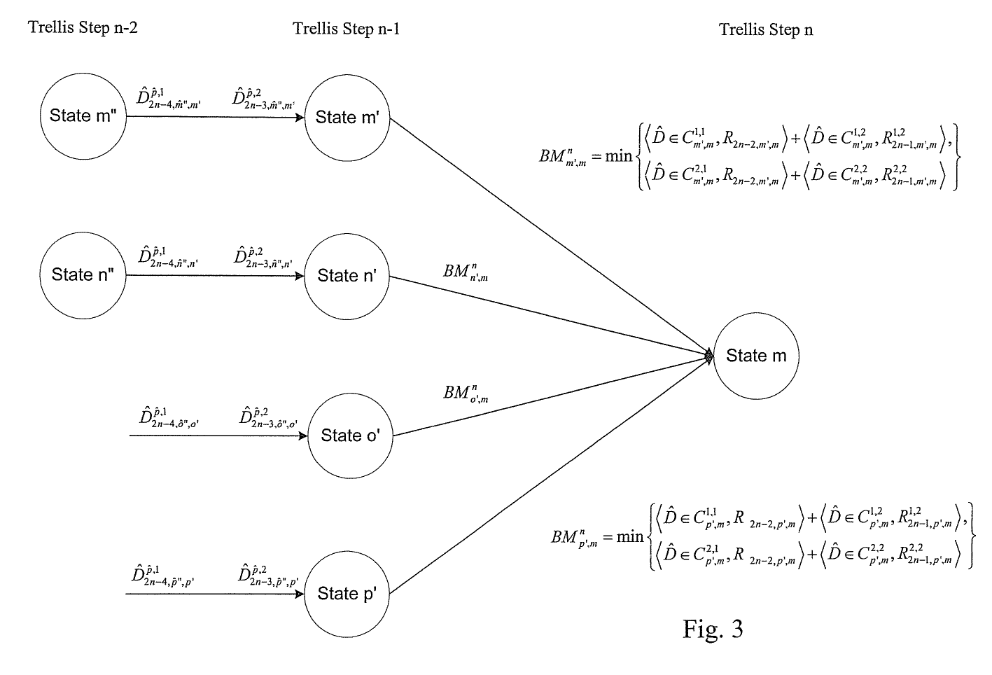

FIG. 3 illustrates an exemplary portion of a trellis during the determination of the state metrics for trellis step n. At each state in the trellis, a determination must be made as to which of the 4 input paths result in the lowest cumulative state metric. To do this, the branch metric associated with each path into the state is determined, and this value added to the cumulative state metric from the state in which the branch originated. The lowest of the four values is then chosen to determine the survivor path.

In FIG. 3, there are 4 paths that converge into state in and originate in 4 distinct states {m′, n′, o′, p′}. These states have selected their survivor paths at time n−1 and the states from which these paths originate are labeled {m″, n″, o″, and p″}. Only m″ and n″ are shown, however, to help emphasize that these states are not necessarily distinct, but rather that the survivor paths for different states can originate from the same previous state, but the 4 possible paths into any 1 state are all different. For FIG. 3, the following expression is given for the branch metric:

$${BM}_{{ }^{{m}^{′} , m}}^{″} = min \{ \begin{matrix}〈 \hat{D} ∈ {C}_{{m}^{′} , m}^{1 , 1} , {R}_{2 n - 2 , {m}^{′} , m}^{1 , 1} 〉 + 〈 \hat{D} ∈ {C}_{{m}^{′} , m}^{1 , 2} , {R}_{2 n - 1 , {m}^{′} , m}^{1 , 2} 〉 , \\ 〈 \hat{D} ∈ {C}_{{m}^{′} , m}^{2 , 1} , {R}_{2 n - 2 , {m}^{′} , m}^{2 , 1} 〉 + 〈 \hat{D} ∈ {C}_{{m}^{′} , m}^{2 , 2} , {R}_{2 n - 1 , {m}^{′} , m}^{2 , 2} 〉\end{matrix} \} \qquad ( 4 )$$

where n is the trellis step, m′ is the previous state, in is the current state, D is as defined above, and R is the output of the MFDQ algorithm with the proper associated feedback term. Note that all R_{2n-2,m′,m}^{i,j} are the same for the same value of 2n−2 and m′.
Thus, in FIG. 3, the superscripts i,j are dropped for this reason. The R_{2n-1,m′,m}^{i,j} term values are not the same however. This is because the first received point on a branch uses the constellation point determined by the survivor path. The survivor path is the same for all four branches exiting a given state and therefore the received point used for the Euclidean distance determination will be the same for the first coset on each branch, e.g., tone 2n−2, or any even tone value. The second tone on the branch, e.g., tone 2n−1, or any odd tone values, however, use feedback dependent on the coset labels of the branch, which is not necessarily the same for all branches. In practice, this means that for the 4D Wei code, one point using the MFDQ-DF for the R_{2n-2,m′,m}^{i,j} term will be determined and an additional four points using the MFDQ-DF for the four possible R_{2n-1,m′,m}^{i,j} term values determined.

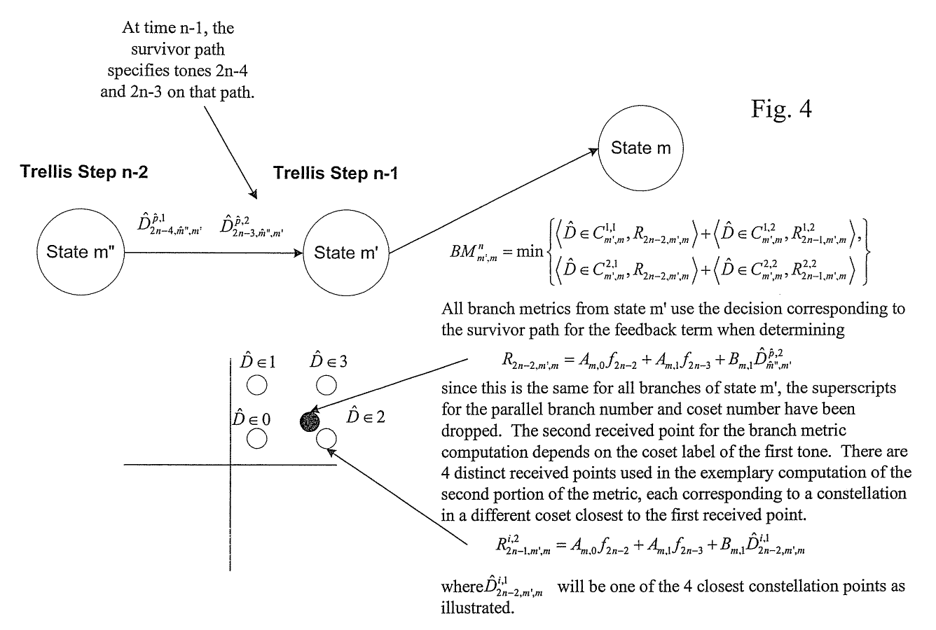

FIG. 4 illustrates this point in greater detail. Specifically, trellis steps n−2, n−1 and n are shown. At time n−1, the survivor paths specifies tones 2n−4 and 2n−3 on that path. All branch metrics from state in' use the decision corresponding to the survivor path for the feedback term when determining

R_{2n-2,m′,m}=A_{m,0}f₂ₙ₋₂+A_{m,1}f₂ₙ₋₃+B_{m,1}\hat{D}_{\hat{m}″,m′}^{\hat{p},2}

since this is the same for all branches of state m′, the superscripts for the parallel branch number and coset number have been dropped. The 2^{nd} received point for the branch metric computation depends on the coset label of the first tone. There are four distinct received points used in the exemplary computation of the second portion of the metric, each corresponding to a constellation in a different coset closest to the 1^{st} received point. Therefore,

R_{2n-1,m ,m}^{i,2}=A_{m,0}f₂ₙ₋₂+A_{m,1}f₂ₙ₋₃+B_{m,1}\hat{D}_{2n-2,m′,m}^{i,1}

where \hat{D}_{2n-1,m′,m}^{i,1} is one of the four closest constellation points.

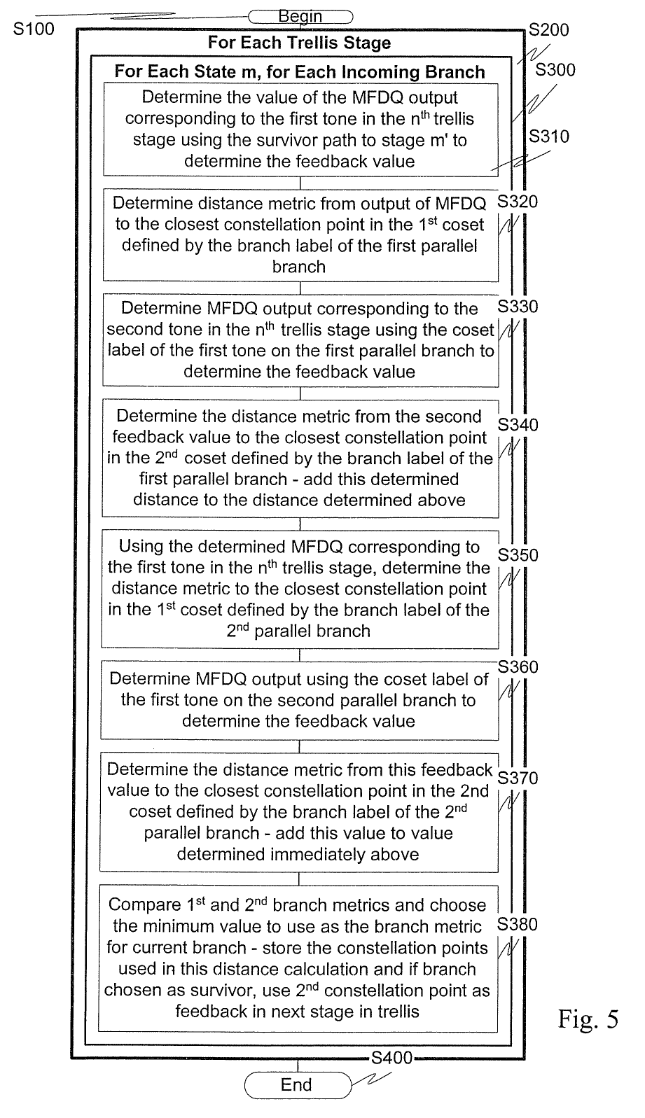

FIG. 5 is a flowchart outlining an exemplary method of determining the MFDQ-DF and trellis branch metric. In particular, control begins in step S100 and continues to step S200. For each trellis stage in step S200, the steps in step S300 are performed. In particular, in step S300, for each state n, for each incoming branch, steps S310 through S380 are performed. Specifically, in step S310, the value of the MFDQ output corresponding to the first tone in the n^{th} trellis stage is determined using the survivor path to stage m′ to determine the feedback value. Next, in step S320, the distance metric from the output of the MFDQ to the closest constellation point in the first coset defined by the branch label of the first parallel branch is determined. Then, in step S330, the MFDQ output corresponding to the second tone in the n^{th} trellis stage is determined using the coset label of the first tone on the first parallel branch to determine the feedback value. Control then continues to step S340.

In step S340, the distance metric from the second feedback value to the closest constellation point and the second coset where the branch label of the first parallel branch is determined and added to the distance determined above. Next, in step S350, the determined MFDQ corresponding to the first tone in the n^{th} trellis stage is used to determine the distance metric to the closest constellation point in the first coset defined by the branch label of the second parallel branch. Then, in step S360, the MFDQ output is determined using the coset label as a first tone on the second parallel branch to determine the feedback value. Control then continues to step S370.

In step S370, the distance metric from this feedback value to the closest constellation point in the second coset defined by the branch label of the second parallel branch is determined and added to the feedback value in step S360. Next, in step S380, the first and second branch metrics are compared and the minimum value chosen to use as the branch metric for the current branch. The constellation points associated with the distance calculation are stored and if the branch is chosen as a survivor, the second constellation point is used for feedback in the stage of the trellis.

If each state m, for each incoming branch is complete, control continues back to step S200 where the steps are again performed for each trellis stage. Upon completion of each trellis stage control continues to step S400 where the control sequence ends.

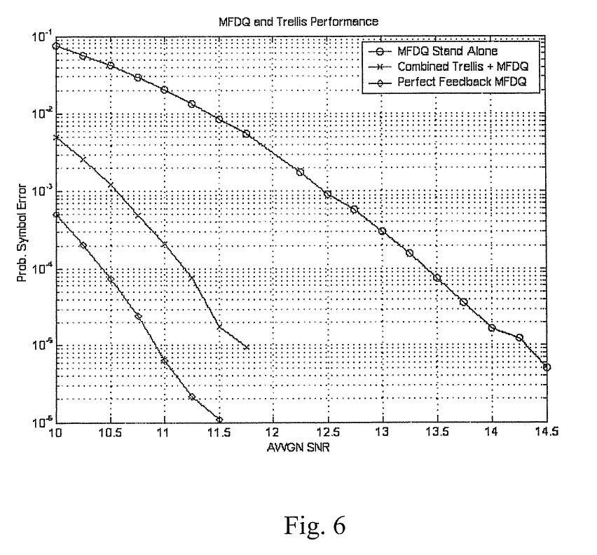

FIG. 6 illustrates exemplary performance improvement associated with using the branch metric for an MFDQ-DF equalizer with 2 feedforward taps and 1 feedback tap. In this particular, exemplary simulation, a channel of ISI was used and the AWGN was varied to get different error rates. The plot illustrates the QAM symbol error rate after the trellis decoder for three different cases. The right-most curve shows the error rate performance for the case where the MFDQ-DF and the trellis are operating independently. The middle curve depicts the case where the branch metric has been altered as described above. The last case shows the performance when the detector uses the actual transmitted QAM point as the feedback point in the MFDQ-DF algorithm, which is the ideal case and serves as a lower bound to the achievable error rate. In this particular example, the algorithm achieves performance to <1 dB of the ideal case and is thus more significant in the case where the MFDQ-DF and trellis are operated independently.

The above-described system can be implemented on a telecommunications device, such a modem, a DSL modem, an ADSL modem, a multicarrier transceiver, a VDSL modern, or the like, or on a separate programmed general purpose computer having a communications device. However, the systems and methods of this invention can also be implemented on a special purpose computer, a programmed microprocessor or microcontroller and peripheral integrated circuit element, and ASIC or other integrated circuit, a digital signal processor, a hard-wired electronic or logic circuit such as discrete element circuit, a programmable logic device such as PLD, PLA, FPGA, PAL, modem, receiver, or the like. In general, any device capable of implementing a state machine that is in turn capable of implementing the flowchart illustrated herein can be used to implement the various methods according to this invention.

Furthermore, the disclosed methods may be readily implemented in software using object or object-oriented software development environments that provide portable source code that can be used on a variety of computer or workstation hardware platforms. Alternatively, the disclosed system may be implemented partially or fully in hardware using standard logic circuits or VLSI design. Whether software or hardware is used to implement the systems in accordance with this invention is dependent on the speed and/or efficiency requirements of the system, the particular function, and the particular software or hardware systems or microprocessor or microcomputer systems being utilized. The systems and methods illustrated herein however can be readily implemented in hardware and/or software using any known or later developed systems or structures, devices and/or software by those of ordinary skill in the applicable art from the functional description provided herein and with a general basic knowledge of the computer and telecommunications arts.

Moreover, the disclosed methods may be readily implemented in software executed on programmed general purpose computer, a special purpose computer, a microprocessor, or the like. In these instances, the systems and methods of this invention can be implemented as program embedded on personal computer such as JAVA® or CGI script, as a resource residing on a server or graphics workstation, as a routine embedded in a dedicated combined trellis and feedback system, or the like. The system can also be implemented by physically incorporating the system and method into a software and/or hardware system, such as the hardware and software systems of a communications transceiver.

It is, therefore, apparent that there has been provided, in accordance with the present invention, systems and methods for combined frequency domain equalization with decision feedback and trellis decoding. While this invention has been described in conjunction with a number of embodiments, it is evident that many alternatives, modifications and variations would be or are apparent to those of ordinary skill in the applicable arts. Accordingly, it is intended to embrace all such alternatives, modifications, equivalents and variations that are within the spirit and scope of this invention.

1. (canceled)

2. A multi-tap frequency domain equalizer.
